(19) United States
(12) Patent Application Publication
(10) Pub. No.: US 2021/0088770 A1
(43) Pub. Date: Mar. 25, 2021

(54) POSE ESTIMATION USING SEMATIC SEGMENTATION

(71) Applicant: FEI Company, Hillsboro, OR (US)

(72) Inventors: John Flanagan, Hillsboro, OR (US); Brad Larson, Portland, OR (US); Thomas Miller, Portland, OR (US)

(73) Assignee: FEI Company, Hillsboro, OR (US)

(21) Appl. No.: 16/580,957

(22) Filed: Sep. 24, 2019

(51) Int. Cl. G02B 21/36; G06T 3/00; G06T 7/33; G06N 3/08; G02B 21/00

(52) U.S. Cl. CPC G02B 21/367; G06T 3/0006; G02B 21/0032; G06N 3/08; G06T 7/33

(57) ABSTRACT

Methods and systems for implementing artificial intelligence to determine the pose of a sample within a microscope system and aligning said sample are disclosed. An example method includes receiving an image of the sample in the microscope apparatus, accessing a template associated with the sample. The template describes a plurality of template key points of the template version of the sample. A plurality of key points on the sample are then determined, where each of the key points on the sample corresponds to a corresponding template key point of a sample template, and the key points are subsequently used to determine a transformation between the sample as depicted in the image and the template version of the sample as described in the template. The transformation can then be used to automate the alignment of the sample within the microscope.

### BACKGROUND OF THE INVENTION

Sample alignment and stability is a core challenge to evaluation of samples in microscope systems. This historically has involved a skilled operator identifying the location of the sample and then adjusting the sample such that it is in a desired position and/or orientation. This identification of the location of the sample by the skilled operator, however, can be tedious and void of robustness. Additionally, to increase productivity and reduce costs it is desired to streamline sample evaluation by removing as much unnecessary human interaction with the process as possible.

For these reasons, current microscope systems are being developed that automate various steps of the sample evaluation process. For example, current microscope systems attempt automatic various sample alignment processes (e.g., tilt alignment, eucentric alignment, drift control, etc.) via a variety of image processing algorithms and system manipulations that find the location of the sample in an image generated by the microscope system. Many techniques exist for automating the step of identifying the location of the sample in such an image, including algorithms utilizing cross correlation, edge matching, and geometric shape matching. However, while current automation techniques exhibit subpixel matching precision when identifying the location of a sample in an image, they struggle to identify samples that have been morphed, altered, and/or damaged. Accordingly, it is desired to have a microscope system that can automatically identify within an image the position of a sample that has been morphed, altered, and/or damaged.

### SUMMARY

Methods and systems for implementing artificial intelligence to determine the pose of a sample within a microscope system and aligning said sample are disclosed. An example method includes receiving an image of the sample in the microscope apparatus, accessing a template associated with the sample. The template describes a plurality of template key points of the template version of the sample. A plurality of key points on the sample are then determined, where each of the key points on the sample corresponding to a corresponding template key point of a sample template, and the key points are subsequently used to determine a transformation between the sample as depicted in the image and the template version of the sample as described in the template. The transformation can then be used to automate the alignment of the sample within the microscope.

Systems for automatically orienting a sample in the microscope system, comprise a sensor or detector configured to generate an image of the sample in the microscope system, and a sample holder configured to hold the sample, and which is configured to at least one of translate, rotate, and tilt the sample within the microscope system. The systems further include one or more processors, and a memory storing non-transitory computer readable instructions, that when executed by the one or more processors, cause the microscope system to implement artificial intelligence to determine the pose of a sample within the microscope system and align said sample.

### BRIEF DESCRIPTION OF THE DRAWINGS

The detailed description is described with reference to the accompanying figures. In the figures, the left-most digit(s) of a reference number identify the figure in which the reference number first appears. The same reference numbers in different figures indicates similar or identical items.

FIG. 1 illustrates example charged particle environment for automatically orienting a sample in a charged particle system.

FIG. 2 depicts a sample process for determining the pose of a sample in a microscope system.

FIG. 3 shows a set of diagrams that illustrate a process for determining the pose of a lamella within a microscope system.

FIG. 4 shows a set of diagrams that illustrate a process for determining the pose of an integrated circuit within a microscope system.

FIG. 5 is a diagram that illustrates the application of automatic pose estimation techniques according to the present invention to an image of a sample in a microscope image.

Like reference numerals refer to corresponding parts throughout the several views of the drawings. Generally, in the figures, elements that are likely to be included in a given example are illustrated in solid lines, while elements that are optional to a given example are illustrated in broken lines. However, elements that are illustrated in solid lines are not essential to all examples of the present disclosure, and an element shown in solid lines may be omitted from a particular example without departing from the scope of the present disclosure.

### DETAILED DESCRIPTION OF EMBODIMENTS

Methods and systems for machine learning enhanced pose estimation are disclosed herein. More specifically, the disclosure includes improved methods and systems that utilize machine learning to orient and/or position samples within charged particle microscope systems. The methods and systems disclosed herein automatically identify key points on a sample within an image obtained by the charged particle system, and then use a template version of the sample to determine a transformation between the sample within the image and the desired orientation and/or position. In this way, charged particle systems according to the present disclosure are able to automate the positioning and/or orientation of samples. However, this is only an illustration of a particular application of the invention disclosed herein, and the methods and system may be used to determine desired transformations of other objects for other applications.

One solution to the above disclosed problem includes neural network image processing to segment images, label some or all pixels of the image with one or more class designations, and determine key points of an object within the image. The key points within the image can then be compared to a template that describes the key points with regard to a template object. Methods and systems can then perform a one to one mapping of each key point as located in the image to the corresponding key points as described in the template to determine a pose the object within the image. Because (1) the segmentation into one or more classes is performed by the neural network, and (2) a one to one mapping of key points between the image and template is conducted, the ability of the disclosed invention to recognize deformed structures is greatly improved over current image processing technology, to provide one example of improvement.

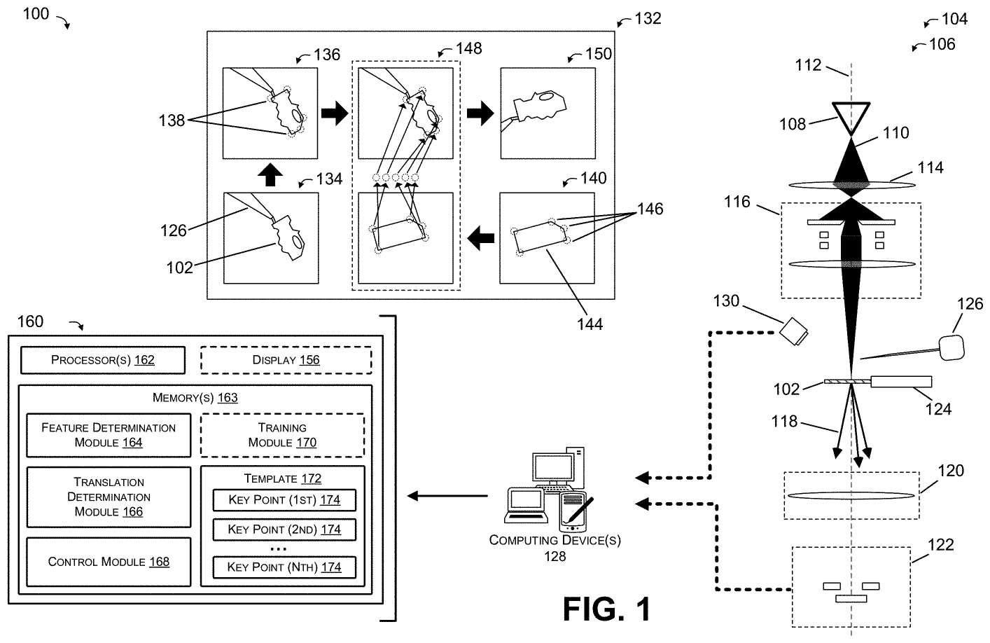

FIG. 1 is an illustration of example charged particle environment 100 for automatically orienting a sample 102 in a charged particle system 104. Specifically, FIG. 1 shows example charged particle environment 100 as including example charged particle system(s) 104 for investigation and/or analysis of a sample 102. The example charged particle system(s) 104 may be or include one or more different types of optical, and/or charged particle microscopes, such as, but not limited to, a scanning electron microscope (SEM), a scanning transmission electron microscope (STEM), a transmission electron microscope (TEM), a charged particle microscope (CPM), a cryo-compatible microscope, focused ion beam microscope (FIBs), dual beam microscopy system, or combinations thereof. FIG. 1 shows the example charged particle microscope system(s) 104 as being a transmission electron microscope (TEM) 106.

The example charged particle microscope system(s) 104 includes a charged particle source 108 (e.g., a thermal electron source, Schottky-emission source, field emission source, etc.) that emits an electron beam 110 along an emission axis 112 and towards an accelerator lens 114. The emission axis 112 is a central axis that runs along the length of the example charged particle microscope system(s) 104 from the charged particle source 108 and through the sample 102. The accelerator lens 114 that accelerates/decelerates, focuses, and/or directs the electron beam 110 towards a focusing column 116. The focusing column 116 focuses the electron beam 110 so that it is incident on at least a portion of the sample 102. In some embodiments, the focusing column 116 may include one or more of an aperture, scan coils, and upper condenser lens. The focusing column focuses electrons from electron source into a small spot on the sample. Different locations of the sample 102 may be scanned by adjusting the electron beam direction via the scan coils. Additionally, the focusing column 116 may correct and/or tune aberrations (e.g., geometric aberrations, chromatic aberrations) of the electron beam 110.

Electrons 118 passing through sample 102 may enter projector 120. In one embodiment, the projector 120 may be a separate part from the focusing column 116. In another embodiment, the projector 120 may be an extension of the lens field from a lens in focusing column 116. The projector 120 may be adjusted so that direct electrons 118 passed through the sample 102, impinge on a microscope detector system 122.

In FIG. 1, the microscope detector system 122 is illustrated as including a disk-shaped bright field detector and dark field detector(s). In some embodiments, the microscope detector system 122 may include one or more other detectors. Alternatively, or in addition, the microscope detector system 122 may include a scanning electron microscope detector system, a focused ion beam detector system, a scanning electron microscope secondary electron detector system, a focused ion beam secondary electron detector system, and an optical microscope detector system.

FIG. 1 further illustrates the example charged particle microscope system(s) 104 as further including a sample holder 124, a sample manipulation probe 126, computing devices 128, and one or more imaging sensor(s) 130. While shown in FIG. 1 as being mounted above the sample 102, a person having skill in the art would understand that imaging sensors 130 may be mounted at other locations within the example charged particle microscope system(s) 104, such as but not limited to, below the sample 102 (e.g., proximate to the microscope detector system 122). The sample holder 124 is configured to hold the sample 102, and is able to translate, rotate, and/or tilt the sample 102 in relation to the example charged particle microscope system(s) 104. Similarly, the sample manipulation probe 120 is configured to hold, transport, and/or otherwise manipulate the sample 102 within the example charged particle microscope system(s) 104. For example, in a dual beam charged particle microscope system, the sample manipulation probe 120 may be used to transport a lamella created from a larger object to a position on the sample holder 118 where the lamella can be investigated and/or analyzed by the charged particle microscope system.

The computing device(s) 128 are configured to generate images of sample 102 within the example charged particle microscope system(s) 104 based on sensor data from the imaging sensor(s) 130, microscope detector system 122, or a combination thereof. In some embodiments, the images are grayscale images that show contrasts indicative of the shape and/or the materials of the sample. Imaging sensor(s) 130 are configured to detect backscattered, secondary, or transmitted electrons, that are emitted from the sample as a result of the sample being irradiated with a charged particle beam. For example, an electron and/or ion source (e.g., charged particle source 108) to irradiate the sample with a respective beam of charged particles. In some embodiments, the irradiating the sample includes scanning the charged particle beam imaging such that it is moved across the sample. The computing device(s) 128 are further configured to determine the position and/or orientation of the sample 102 as depicted by the images. In some embodiments, the computing device(s) 128 are further executable to cause the sample holder 124, the sample manipulation probe 126, or another component of the example charged particle microscope system(s) 104 to translate and/or reorient the sample 102.

Those skilled in the art will appreciate that the computing devices 128 depicted in FIG. 1 are merely illustrative and are not intended to limit the scope of the present disclosure. The computing system and devices may include any combination of hardware or software that can perform the indicated functions, including computers, network devices, internet appliances, PDAs, wireless phones, controllers, oscilloscopes, amplifiers, etc. The computing devices 128 may also be connected to other devices that are not illustrated, or instead may operate as a stand-alone system. In addition, the functionality provided by the illustrated components may in some implementations be combined in fewer components or distributed in additional components. Similarly, in some implementations, the functionality of some of the illustrated components may not be provided and/or other additional functionality may be available.

It is also noted that the computing device(s) 128 may be a component of the example charged particle microscope system(s) 104, may be a separate device from the example charged particle microscope system(s) 104 which is in communication with the example charged particle microscope system(s) 104 via a network communication interface, or a combination thereof. For example, an example charged particle microscope system(s) 104 may include a first computing device 128 that is a component portion of the example charged particle microscope system(s) 104, and which acts as a controller that drives the operation of the example charged particle microscope system(s) 104 (e.g., adjust the scanning location on the sample 102 by operating the scan coils, etc.). In such an embodiment the example charged particle microscope system(s) 104 may also include a second computing device 128 that is desktop computer separate from the example charged particle microscope system(s) 104, and which is executable to process data received from the imaging sensor(s) 130 to generate images of the sample 102 and/or perform other types of analysis. The computing devices 128 may further be configured to receive user selections via a keyboard, mouse, touchpad, touchscreen, etc.

FIG. 1 also depicts a visual flow diagram 132 that includes a plurality of images that together depict an example process that may be performed by the computing device(s) 128 to translate and/or reorient the sample 102. For example, image 134 shows an image of a sample 102 being held by a sample manipulation probe 126. Image 136 illustrates the computing device(s) 128 identifying a plurality of key points 138 on the sample 102, and may determine a pose of the sample 102 within the example charged particle microscope system(s) 104 based on the key points. The computing device(s) 128 identifying the plurality of key points 138 may include applying an analytical neural network to the image 134 that is trained to identify key points 138.

Image 140 corresponds to a template that depicts a template sample 144 and a plurality of template key points 146. In some embodiments, the template depicts the template sample 144 in a desired position and/or orientation. The combination image 148 shows the computing device(s) 128 mapping each of the template key points 146 to the key points 138 in a one to one correspondence. Based on this matching, the computing device(s) 128 is then able to determine a transformation between the position and/or orientation of the template sample 144 and the sample 102 depicted in image 134, and then can cause the sample holder 124, the sample manipulation probe 126, or another component of the example charged particle microscope system(s) 104 to translate and/or reorient the sample 102 such that it is in a desired position and/or orientation. Image 150 shows the sample 102 after it has been translated, rotated, and/or tilted such that it is in the desired position and/or orientation.

FIG. 1 further includes a schematic diagram illustrating an example computing architecture 160 of the computing devices 128. Example computing architecture 160 illustrates additional details of hardware and software components that can be used to implement the techniques described in the present disclosure. Persons having skill in the art would understand that the computing architecture 160 may be implemented in a single computing device 128 or may be implemented across multiple computing devices. For example, individual modules and/or data constructs depicted in computing architecture 160 may be executed by and/or stored on different computing devices 128. In this way, different process steps of the inventive method according to the present disclosure may be executed and/or performed by separate computing devices 128.

In the example computing architecture 160, the computing device includes one or more processors 162 and memory 163 communicatively coupled to the one or more processors 162. The example computing architecture 160 can include a feature determination module 164, a transformation determination module 166, a control module 168, and a training module 170 stored in the memory 163. The example computing architecture 160 is further illustrated as including a template 172 that identifies a plurality of key points 174 stored on memory 163. The template 172 is a data structure that describes a template object, such as but not limited to the size, shape, and template key points 174 of the template object. In some embodiments, the template object corresponds to a template sample 144. For example, the template 172 describes the positional relationships between each key point 174 and the template object. Each of the key points 174 corresponds to a specific feature or point on the template shape that a feature determination module 164 is trained to identify. In some embodiments, the template 172 may also identify a desired alignment of the template object (i.e., a position, rotation, and/or tilt of the template object in relation to a coordinate system of a microscope or image). For example, the template 172 may identify the position of a plurality of template key points 174 that correspond to the template object being in a desired orientation for a specific process (e.g., imaging a sample, milling a sample, analyzing a specific feature of a sample, etc.). In some embodiments, the template 172 may be manipulated. For example, the template 172 may correspond to a 3-D model of the template object that allows a user of a computing device 128 to modify the position and/or orientation of the template object via a graphical user interface presented on a display 156 of a computing device 128. In such embodiments, this allows the template 172 to be modified so that it describes the template object in a specific desired position and/or orientation.

As used herein, the term “module” is intended to represent example divisions of executable instructions for purposes of discussion, and is not intended to represent any type of requirement or required method, manner or organization. Accordingly, while various “modules” are described, their functionality and/or similar functionality could be arranged differently (e.g., combined into a fewer number of modules, broken into a larger number of modules, etc.). Further, while certain functions and modules are described herein as being implemented by software and/or firmware executable on a processor, in other instances, any or all of modules can be implemented in whole or in part by hardware (e.g., a specialized processing unit, etc.) to execute the described functions. As discussed above in various implementations, the modules described herein in association with the example computing architecture 160 can be executed across multiple computing devices 128.

The feature determination module 164 can be executable by the processors 162 to determine key points 174 of an object within an image. In some embodiments, the feature determination module 164 can be executable by the processors 162 to determine key points 174 of an object within an image of a sample 102 obtained by example charged particle microscope system(s) 104. The feature determination module 164 may comprise a trained machine learning module (e.g., an artificial neural network (ANN), convolutional neural network (CNN), Fully Convolution Neural Network (FCN) etc.) that is able to identify regions and/or points within an image that correspond to key points 174. In some embodiments, the feature determination module 164 may identify the key points 174 of the object within the image by processing the image with a neural network (e.g., ANN, CNN, FCN, etc.) that outputs one or more coordinates of locations within the image that are predicted to correspond to key points on the object. In such embodiments, outputs of the neural network may also include labels that identity the particular key point 174 that is predicted to be located at each of the corresponding coordinates. Alternatively, the feature determination module 164 may identify the key points within an image by performing an image segmentation step, and then performing a key point identification step. In the image segmentation step, the feature determination module 164 may segment the image into classes of associated pixels of the image. Example classes of associated pixels may include, but is not limited to a body of an object, a boundary of an object, surface structure of an object, component materials, component features, boundaries, etc. In the key point identification step the feature determination module 164 may determine the key points 174 based on the segmented image. For example, the feature determination module 164 may be trained to identify specific key points within the segmented image based on segmentation distributions that are indicative of the specific key points. Feature determination module 164 may also determine the key points directly from the image.

The transformation determination module 166 can be executable by the processors 162 to utilize the key points identified by the feature determination module 164 to determine a transformational difference between a position/orientation of an object in the image and a desired position/orientation. Specifically, the transformation determination module 166 is executable to determine a pose of an object based on the key points 174 in the image with respect to the template 172. As discussed above, the template 172 is a data structure that describes positional relationships between each key point 174 and the template object. The transformation determination module 166 is able to use these relationships and the key points identified by the feature determination module 164 to map the object in the image to the template object. For example, because the feature determination module 164 is trained to identify specific individual key points 174, this allows the transformation determination module 166 to obtain one to one matches between the specific key points 174 identified by the feature determination module 164 and corresponding key points 174 as described by the template 172. This ability to perform one to one matches enables the transformation determination module 166 to use the template to determine the pose of the object even when there are differences between the template object and the object depicted in the image, including but not limited to non-linear distortions and plastic deformations. For example, the ability to perform one to one matches allows the transformation module 166 to determine the pose of an object even when an edge of the object has been damaged such that it has a different curvature (e.g., includes a cutout, has a different curvature, etc.) than the corresponding edge of the template object.

In some embodiments, where the template 172 is a model associated with sample 102 (e.g., a CAD drawing for a lamella, where the sample is a lamella), the transformation determination module 166 may be executable to determine the pose of sample 102 in an image generated from sensor data from imaging sensors 130, and then determine a transformational difference between the pose of sample 102 and a desired position/orientation of the sample 102 within the image and/or example charged particle microscope system(s) 104. In other words, the transformation determination module 166 may be executable to identify a translation, tilt, rotation, or a combination thereof that, if performed on the sample 102 by the sample holder 124 or sample manipulation probe 126, that would cause the sample 102 to be in a desired position and/or orientation.

In some embodiments, the transformation determination module 166 may be further configured to determine whether there are a sufficient number of matches between template key points and key points identified by the feature determination module 164 to identify the pose and/or transformational difference. For example, when the transformation determination module 166 may compare the number of identified matches with a predetermined threshold. Alternatively, or in addition, the transformation determination module 166 may generate an estimated accuracy of a pose/transformational difference determination based on the number of and/or quality of identified matches, and then compare the estimated accuracy to a predetermined threshold. If the transformation determination module 166 determines that the number of identified matches and/or the estimated accuracy is less than such a threshold, the transformation determination module 166 may stop the process of identifying the pose, present a request to a user of a computing device 128, and or otherwise notify such a user that there is an insufficient number of matches to proceed.

The control module 168 can be executable by the processors 162 to cause a computing device 128 and/or example charged particle microscope system(s) 104 to take one or more actions. For example, the control module 168 may cause the example charged particle microscope system(s) 104 to cause the sample holder 124 or sample manipulation probe 126 to apply a translation, tilt, rotation, or a combination thereof that is identified by the transformation determination module 166, and that once performed cause the sample 102 to be in a desired position and/or orientation.

The computing architecture 160 may optionally include a training module 170 that is executable to train the feature determination module 164 and/or a component machine learning algorithm(s) thereof to identify the key points in an image at salient features of the image. The training module 170 facilitates the training of the feature determination module 164 and/or a component machine learning algorithm based on a training set of one or more labeled images of similar and/or identical objects. The labels of the labeled images may include regions and/or points of the image that correspond to specific key points of an object, sections of the image that correspond to groupings of pixels of a certain class (i.e., segmentation information). The training set of images may be labeled by an expert human operator, by a computing algorithm, or a combination thereof. In some embodiments, the training module 170 may be configured to generate the training set of one or more labeled images from a single labeled image, a model, and/or a CAD drawing of the object. For example, the training module 170 may perform one or more morphing operations on the labeled image, model, and/or CAD drawing to form a plurality of labeled morphed images. The training module 170 may be configured to perform additional training with new training data, and then transmit updates the improve the performance of the feature determination module 164 and/or the component machine learning algorithm(s) thereof.

As discussed above, the computing devices 128 include one or more processors 162 configured to execute instructions, applications, or programs stored in a memory(s) 164 accessible to the one or more processors. In some examples, the one or more processors 162 may include hardware processors that include, without limitation, a hardware central processing unit (CPU), a graphics processing unit (GPU), and so on. While in many instances the techniques are described herein as being performed by the one or more processors 162, in some instances the techniques may be implemented by one or more hardware logic components, such as a field programmable gate array (FPGA), a complex programmable logic device (CPLD), an application specific integrated circuit (ASIC), a system-on-chip (SoC), or a combination thereof.

The memories 163 accessible to the one or more processors 162 are examples of computer-readable media. Computer-readable media may include two types of computer-readable media, namely computer storage media and communication media. Computer storage media may include volatile and non-volatile, removable, and non-removable media implemented in any method or technology for storage of information, such as computer readable instructions, data structures, program modules, or other data. Computer storage media includes, but is not limited to, random access memory (RAM), read-only memory (ROM), erasable programmable read only memory (EEPROM), flash memory or other memory technology, compact disc read-only memory (CD-ROM), digital versatile disk (DVD), or other optical storage, magnetic cassettes, magnetic tape, magnetic disk storage or other magnetic storage devices, or any other non-transmission medium that may be used to store the desired information and which may be accessed by a computing device. In general, computer storage media may include computer executable instructions that, when executed by one or more processing units, cause various functions and/or operations described herein to be performed. In contrast, communication media embodies computer-readable instructions, data structures, program modules, or other data in a modulated data signal, such as a carrier wave, or other transmission mechanism. As defined herein, computer storage media does not include communication media.

Those skilled in the art will also appreciate that items or portions thereof may be transferred between memory 163 and other storage devices for purposes of memory management and data integrity. Alternatively, in other implementations, some or all of the software components may execute in memory on another device and communicate with the computing devices 128. Some or all of the system components or data structures may also be stored (e.g., as instructions or structured data) on anon-transitory, computer accessible medium or a portable article to be read by an appropriate drive, various examples of which are described above. In some implementations, instructions stored on a computer-accessible medium separate from the computing devices 128 may be transmitted to the computing devices 128 via transmission media or signals such as electrical, electromagnetic, or digital signals, conveyed via a communication medium such as a wireless link. Various implementations may further include receiving, sending or storing instructions and/or data implemented in accordance with the foregoing description upon a computer-accessible medium.

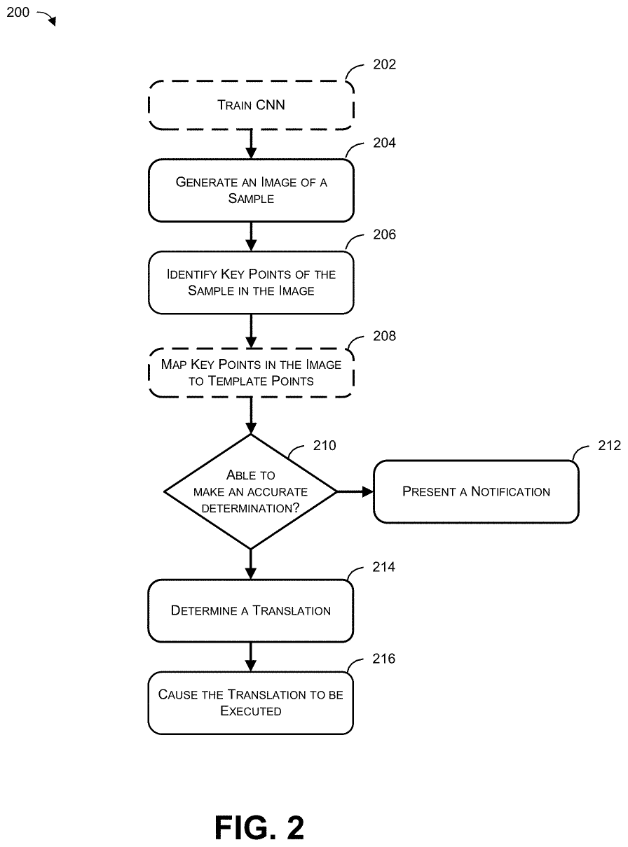

FIG. 2 is a flow diagram of illustrative processes depicted as a collection of blocks in a logical flow graph, which represent a sequence of operations that can be implemented in hardware, software, or a combination thereof. In the context of software, the blocks represent computer-executable instructions stored on one or more computer-readable storage media that, when executed by one or more processors, perform the recited operations. Generally, computer-executable instructions include routines, programs, objects, components, data structures, and the like that perform particular functions or implement particular abstract data types. The order in which the operations are described is not intended to be construed as a limitation, and any number of the described blocks can be combined in any order and/or in parallel to implement the processes.

Specifically, FIG. 2 is a flow diagram of an illustrative process 200 for determining the pose of a sample in a microscope system. The process 200 may be implemented in environment 100 and/or by one or more computing device(s) 128, and/or by the computing architecture 160, and/or in other environments and computing devices.

At 202, a convolutional neural network is trained to identify key points in an image. Specifically, the convolutional neural network (CNN) is trained using a training set of one or more labeled images of a sample. The labels of the labeled images may include, but is not limited to, regions and/or points of the image that correspond to specific key points of a sample, sections of the image that correspond to groupings of pixels of a certain class (i.e., segmentation information). The training set of images may be labeled by an expert human operator, by a computing algorithm, or a combination thereof. For example, the training set may be automatically be generated from a single labeled image, a model, and/or a CAD drawing of the sample by a computing algorithm that morphs and/or otherwise distorts the source labeled image/model/CAD drawing to form a plurality of labeled images. In some embodiments, the CNN may be periodically retrained to improve performance. When such retraining occurs, updates may be transmitted to consumer computing devices executing the systems and methods disclosed herein to improve the performance of the CNN.

At 204, an image of a sample in a microscope system is generated. Specifically, an imaging system of a microscope system generates an image of a sample within the microscope system. In various embodiments the sample may correspond to but is not limited to being one of a lamella, a semiconductor, and a biological sample.

At 206, key points of the sample in the image are identified. Specifically, the CNN is applied to the image of the sample, and the CNN identifies regions and/or points within an image that correspond to key points. The CNN may identify the key points within the image by performing an image segmentation step where the image is segmented into classes of associated pixels, and then performing a key point identification step in which the CNN determines the key points of the sample as depicted in the image based on the segmented image (i.e., based on segmentation distributions of the segmented image that are indicative of the specific key points). The CNN may also directly determine the point location coordinates. Example classes of associated pixels may include, but is not limited to a body of a sample, a boundary of the sample, surface structure of the sample, component materials, component features, boundaries, etc.

At 208, key points in the image are mapped to template key points. That is, each key point in the image is mapped to a corresponding template key point described by a template. The template describes the positional relationship of each template key point with a template version of the sample. In some embodiments, the one to one matching may be performed using a regression analysis (e.g., a fitting routine that identifies a consensus match for each of the key points). Alternatively, the individual key points may be mapped directly to the corresponding template key points. For example, each of the key points may be assigned a label by the CNN. Since the template key points are also labeled, each key point can be directly paired to the corresponding template key point with the same label. By determining one to one matches in this way, the pose of the sample as depicted in the image can be determined even when the sample is morphologically different from the template sample. For example, the one to one matching allows pose of the sample to be determined even when there are differences between the template sample and the sample as depicted in the image, including but not limited to differences in borders, position, rotation, scale, skew, non-linear distortions, etc. Such non-linear differences can occur when matching a template to manually prepared or naturally occurring specimens which are similar but morphologically distinct from the template. For example, when matching cells, it is noted that naturally occurring cells are non-uniform and thus are likely to exhibit morphological differences from a template cell. Additionally, when matching lamella cut by manual operators or automation, such prepared lamella often have morphological differences from a corresponding template that result from any combination of user error, device error, user choice, or other sources of variability inherent to the process of creation of a lamella. In other examples, the sample can be deformed by plastic deformations caused by, but not limited to, the processes of drying, heating, and/or irradiating the sample.

At 210, it is determined whether the system is able to make an accurate determination. Such a determination may be made via a comparison between the number of identified matches with a predetermined threshold, the quality of the identified matches, an estimated accuracy of a pose/transformational difference determination made using the matches, or a combination thereof. For example, the system may determine an estimated accuracy of a pose/transformational difference that can be determined using the identified key point matches, and then compare the estimated accuracy with a predetermined threshold.

If the answer at 210 is no, the process continues to step 212, and a request/notification may be presented to a user of via a graphical user interface that indicates that there is an insufficient number of matches to proceed. Alternatively, if the answer at 210 is yes, the process continues to step 214, and a transformation is determined. The transformation determined corresponds to a translation, tilt, rotation, scale/magnification adjustment, and/or a combination thereof that, if performed on the sample would cause the sample to be in a desired position and/or orientation. Specifically, the key points of the sample as depicted in the image are used to determine a transformation between a position/orientation of a sample in the image and a desired position/orientation. In some embodiments, the template describes the desired position/orientation of the sample, and the transformation is determined using the template.

At 216 the transformation is optionally executed such that the sample is in the desired position. Specifically, a control module associated with the microscope system may cause a sample holder and/or a sample manipulation probe to apply a translation, tilt, rotation, magnification change or a combination thereof that corresponds to the transformation. In this way, after such a translation/tilt/rotation/magnification adjustment is applied the sample is in the desired position. In some embodiments, after the translation/tilt/rotation/magnification adjustment is applied a new image of the sample is generated, and the system determines the pose of the sample in the new image. This allows the system to verify that the sample is now in the desired position and/or orientation.

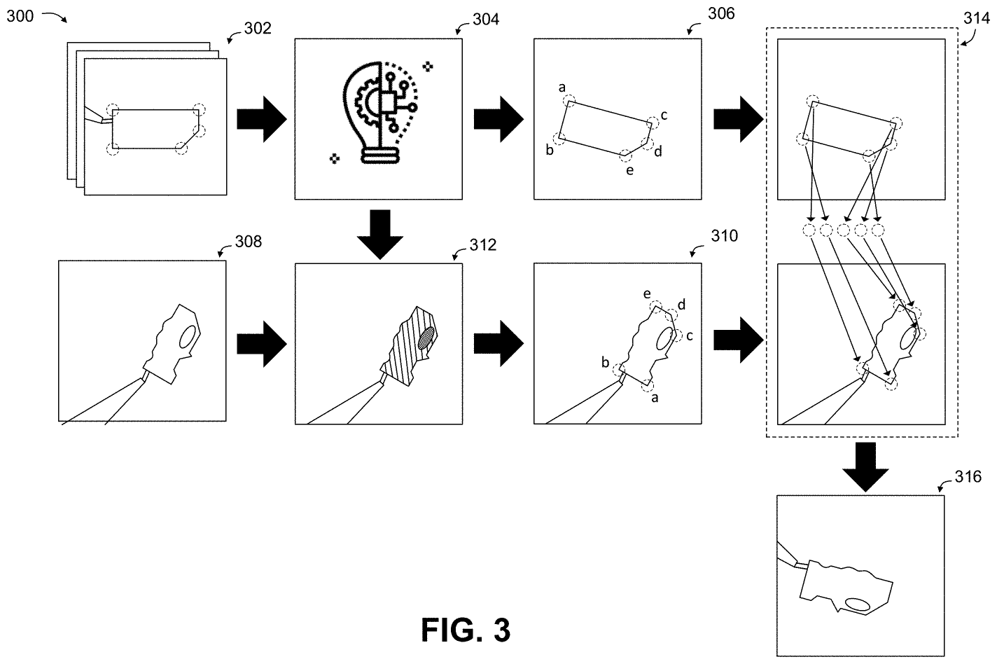

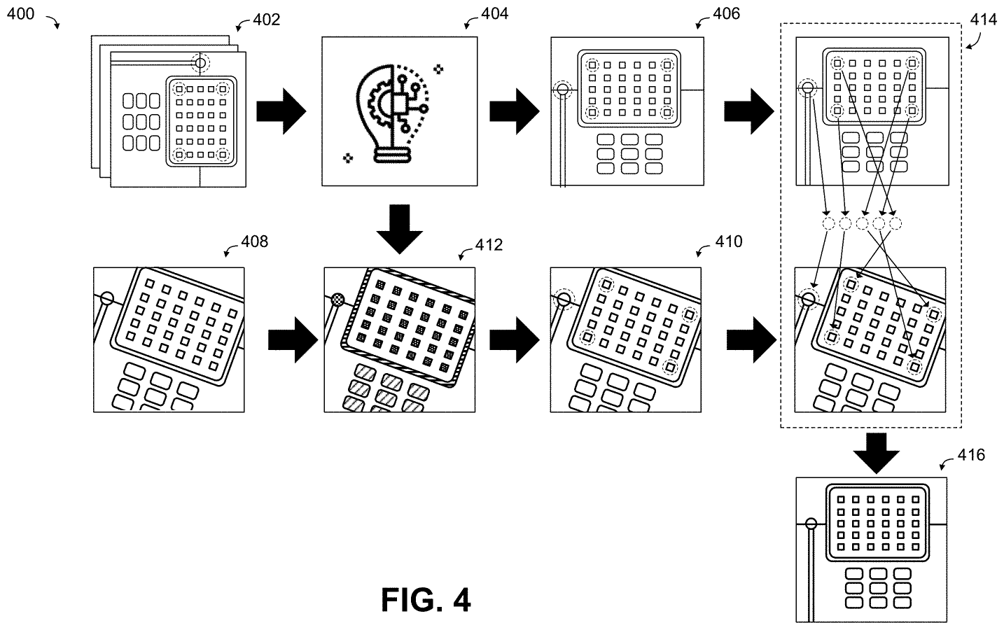

FIGS. 3 and 4 are diagrams that illustrate sample process 300 and 400 for determining the pose of various types of samples. FIG. 3 is a set of diagrams that illustrate a process 300 for determining the pose of a lamella within a microscope system. Specifically, FIG. 3 shows a depiction of a plurality of labeled images of lamellae 302 that are used to train a machine learning algorithm 304. In some embodiments, the machine learning algorithm 304 produces a template 306 that describes a relationship between a lamella and a set of key points.

FIG. 3 further illustrates an image of a lamella within a microscope system 308 that has been generated by an imaging system of the microscope system. In depiction 308, the lamella is attached to a sample manipulation probe. The lamella in image 308 is also depicted as having non-linear boundaries and features that are not present in either the lamellae in the plurality of labeled images 302 or the template 306.

The machine learning algorithm 304 may be applied to the image of the lamella 308 to obtain a labeled image of the lamella 310. In some embodiments, the machine learning algorithm 304 first generates a segmented image of the lamella 312, and then generates the labeled image 310 based on the segmented image 312. The combination image 314 shows the individual labeled key points in the template image 306 being mapped to the identified key points in the labeled image 310. The pose of the lamella as depicted in image 308 is then determined based on this matching. Because the key points between 306 and 310 are mapped in a one to one match the process 300 allows for the pose of the lamella in image 308 to be determined even when the lamella in image 308 is misshapen or has features not included in the lamellae depicted in the training images 302 of the template 306. In some embodiments, process 300 may further include determining the transformation between the pose of the lamella in image 308 and a desired pose of the lamella. In such embodiments, the transformation may be applied to the lamella within the microscope system so that it is caused to be in the desired position/orientation. For example, image 316 shows an image of the lamella in the microscope system after the sample manipulation probe has applied the determined transformation to the lamella. After the determined transformation is applied, the process 300 may be repeated to find the pose of the lamella within the microscope system to verify that the lamella is in the desired position.

FIG. 4 shows a set of diagrams that illustrate a process 400 for determining the pose of an integrated circuit within a microscope system. Initially, FIG. 4 shows a depiction of a plurality of labeled images of integrated circuits 402 that are used to train a machine learning algorithm 404. In some embodiments, the machine learning algorithm 404 produces a template 404 that describes a relationship between a template integrated circuit and a set of key points. Process 400 is further depicted as including an image of an integrated circuit 408 within a microscope system.

The integrated circuit in image 408 is also depicted as having a different scale and rotation as the integrated circuits in the plurality of labeled images 402 or the template 406. The machine learning algorithm 404 can be applied to the image of an integrated circuit 408 to obtain labeled image 410 of the integrated circuit within the microscope system. While not necessary, the machine learning algorithm 404 may first generate a segmented image of the integrated circuit 412, and then generate the labeled image 410 of the integrated circuit based on the segmented image 412. The combination image 414 shows the individual labeled key points in the template image 414 being mapped to the identified key points in the labeled image 414. The pose of the integrated circuit as depicted in image 408 is then determined based on this matching.

In some embodiments, a transformation between the pose of the integrated circuit in image 408 and a desired pose of the integrated circuit within the microscope system is determined. In such embodiments, the transformation may be applied to the integrated circuit within the microscope system so that it realigned to be in the desired position/orientation. For example, image 416 shows an image of the integrated circuit in the microscope system after the determined transformation has be applied thereto (e.g., by causing a sample holder to translate, rotate, and/or tilt the integrated circuit within the microscope system. The microscope system may also apply a magnification change. In this way, process 400 enables the integrated circuit to be automatically aligned within the microscope system so that it is in the desired position. This may ensure that desired portions of the integrated circuit are evaluated or analyzed, or that subsequent milling procedures (e.g., focused ion beam millings, lamella prep, etc.) are performed on the correct regions of the integrated circuit.

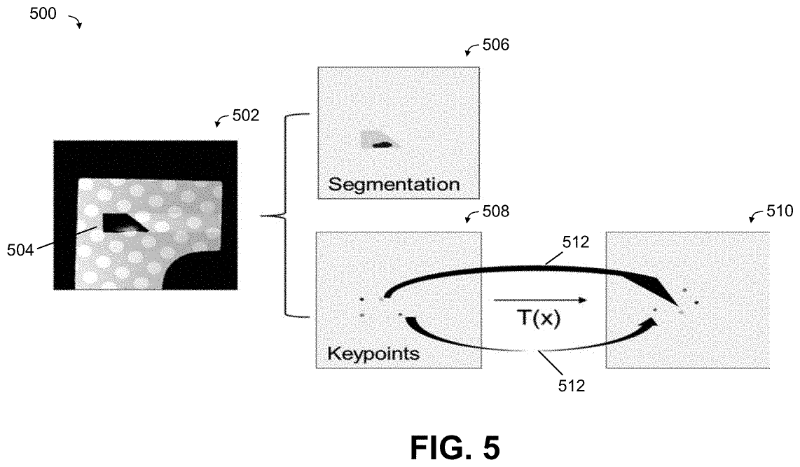

FIG. 5 illustrates the application 500 of automatic pose estimation techniques according to the present invention to an image of a sample in a microscope image. FIG. 5 includes and image 502 of a sample 504 within a charged particle microscope system. FIG. 5 also shows a segmented version of the image 506, and a visualization 508 that shows a number of key points of the sample 502. Each of the segmented image 506 and the visualization 508 were generated by applying a machine learning algorithm to image 502. FIG. 5 further shows the determination of a transformation (T(x)) between the position and/or orientation of the sample 502 within the microscope system and a desired alignment. Image 510 depicts the location of the key points of sample 502 after the transformation (T(x)) has been applied to the sample 502. Arrows 512 indicate the one to one correspondence between individual key points as shown in visualization 508 and their corresponding key points after the transformation has been applied to the sample 502.

Examples of inventive subject matter according to the present disclosure are described in the following enumerated paragraphs.

A1. A method for estimating position of a sample in an electron/charged particle microscope apparatus, the method comprising:

receiving an image of the sample in the electron/charged particle microscope apparatus;

accessing a template associated with the sample, the template describing a template version of the sample in a desired orientation/alignment, the template further including a plurality of template key points of the template version of the sample;

determining a plurality of key points on the sample, each of the key points on the sample corresponding to a corresponding template key point of a sample template; and

determining, based on the key points and the corresponding template key points, a transformation between the sample in the image and the template version of the sample as described in the template.

A1.0.1. The method of paragraph A1, wherein the transformation is a three-dimensional transformation.

A1.0.2. The method of paragraph A1, wherein the transformation is a two-dimensional transformation.

A1.1. The method of any of paragraphs A1-A1.0.2, further comprising causing the sample to be aligned within the electron/charged particle microscope apparatus based on the transformation.

A1.1.1. The method of paragraph A1.1, wherein aligning the sample in the electron/charged particle microscope apparatus comprises aligning the sample so that a sub-sample/lamella is automatically formed from a desired region of the sample.

A1.1.1.1. The method of paragraph A1.1.1, further comprising aligning the sample so that cuts to form the sub-sample/lamella are aligned with one or more desired features.

A1.1.2. The method of any of paragraphs A1.1-A1.1.1.1, wherein the template describes a desired region of the sample from which a sub-sample/lamella is to be formed, and aligning the sample in the electron/charged particle microscope apparatus comprises aligning the sample so that the sub-sample/lamella is automatically formed from the desired region of the sample.

A1.1.3. The method of any of paragraphs A1.1.1-A1.1.2, wherein the subsample/lamella is automatically formed with a focused ion beam (FIB) system.

A1.2. The method of any of paragraphs A1-A1.1, further comprising causing the optics of the electron/charged particle microscope apparatus to be adjusted based on the based on the key points and the corresponding template key points.

A1.2.1. The method of paragraph A1.2, wherein causing the optics of the electron/charged particle microscope apparatus to be adjusted comprises performing one or more microscope column adjustments to modify one or more characteristics of a electron/charged particle beam of the electron/charged particle microscope apparatus.

A1.2.2. The method of paragraph A1.2, wherein causing the optics of the electron/charged particle microscope apparatus to be adjusted comprises adjustment of the microscope optics such as the magnification to bring the desired object to the correct scale.

A1.3. The method of any of paragraphs A1.1.1-A1.1.3, wherein the transformation comprises one or more of a translation, a rotation, a scale adjustment, a skew, or an application of another kind of linear transformation matrix.

A2. The method of any of paragraphs A1-A1.3, wherein receiving the image comprises generating the image of the sample based on sensor data from one or more sensors of the electron/charged particle microscope apparatus.

A2.1. The method of paragraphs A2, wherein the one or more sensors generate the sensor data in response to the sample being irradiated by the electron/charged particle microscope apparatus.

A2.2 The method of any of paragraphs A2-A2.1, wherein the sensor is a camera.

A2.2.1. The method of paragraph A2.2, wherein the camera is one of a CCD, a CMOS, and a Direct Electron Detector.

A3. The method of any of paragraphs A1-A2.1, wherein the key points are point locations within the image of the sample.

A4. The method of any of paragraphs A1-A3, wherein the key points are determined using a convolutional neural network (CNN).

A4.1. The method of paragraph A4, wherein the CNN is a convolutional segmentation neural network.

A4.2. The method of any of paragraphs A4-A4.1, wherein the CNN is trained to predict the key points at salient features of the image.

A4.3. The method of any of paragraphs A4-A4.2, further comprising training the CNN to identify the key points.

A4.3.1. The method of paragraphs A4.3, wherein the CNN is trained with a training set of one or more labeled images of samples.

A4.3.1.1. The method of paragraph A4.3.1, wherein the one or more labeled images of samples are labeled by a human operator.

A4.3.1.2. The method of any of paragraphs A4.3.1-A4.3.1.1, wherein the labels for the training set of one or more labeled images include segmentation information of each corresponding image.

A4.3.1.3. The method of any of paragraphs A4.3.1-A4.3.1.2, wherein the labels for the training set of one or more labeled images include key points of each corresponding image.

A4.3.1.4. The method of any of paragraphs A4.3.1-A4.3.1.3, further comprising generating the training set of one or more labeled images from a single labeled image, model, and/or CAD drawing of the sample.

A4.3.1.4.1. The method of paragraph A4.3.1.4, wherein generating the training set of one or more labeled images from a single labeled image, model, and/or CAD drawing of the sample comprises automatically morphing the image, model, and/or CAD drawing to form a labeled training set.

A5. The method of any of paragraphs A1-A4.3.1.4.1, wherein determining the plurality of key points comprises: segmenting the image to form a segmented image; and determining the key points based on the segmented image.

A5.1. The method of any of paragraphs A1-A5, wherein determining the plurality of key points comprises: performing a direct determination of keys points from a neural network yielding point estimates.

A5.1.1. The method of paragraph A5.1, wherein performing the direct determination comprises: the neural network applying a label to a particular key point; and matching the particular key point to a particular template key point that has the label.

A5.2. The method of any of paragraphs A1-A5.1.1, wherein determining the plurality of key points comprises processing the image of the sample with a convolutional neural network (CNN), wherein an output of the CNN includes coordinates of predicted locations for each of the plurality of key points on the sample within the image of the sample.

A6. The method of any of paragraphs A1-A5.2, wherein determining the transformation comprises performing a regression to determine the transformation.

A7. The method of any of paragraphs A1-A6, wherein determining the transformation comprises determining a pose of the sample in the image, and then determining the transformation based on the pose.

A8. The method of any of paragraphs A1-A7, wherein the sample is a lamella.

A8.1. The method of paragraph A8, wherein the lamella is a lamella sat on a grid, a lamella welded to post, and a lamella attached to a sample manipulation probe.

A9. The method of any of paragraphs A1-A8, wherein the template describes the key points of a template sample in a cartesian coordinate system.

A9.1. The method of paragraph A9, wherein the template is configured such that the orientation of the template sample as described in the template may be adjusted.

A9.2. The method of any of paragraphs A9-A9.1, wherein the template is a three-dimensional model of the template sample, and where a user is able to manipulate an orientation of the template sample so that the template sample is in a desired orientation.

A10. The method of any of paragraphs A1-A9.2, wherein there is a one to one correspondence between each of the key points of the sample in the image and a corresponding template key points.

A11. The method of any of paragraphs A1-A10, wherein determining the corresponding template key point for each of the key points comprises running a fitting routine to identify a consensus match for each of the key points.

A12. The method of any of paragraphs A1-A11, wherein two or more of the key points are associated with a fiducial on the sample.

A13. The method of any of paragraphs A1-A12, wherein the sample is on a probe, and wherein causing the sample to be aligned comprises manipulating the probe so that the sample is in a desired position.

A14. The method of any of paragraphs A1-A12, wherein the sample is on a sample holder, and wherein causing the sample to be aligned comprises manipulating the sample holder so that the sample is in a desired position.

A15. The method of any of paragraphs A1-A14, wherein the sample is one of a lamella, a semiconductor, and a biological sample.

A16. The method of any of paragraphs A1-A15, wherein the sample is a biological sample, the key points correspond to features within the biological sample, and wherein aligning the sample comprises aligning the biological sample so that the electron/charged particle microscope captures an image of a desired portion of the biological sample at a desired orientation.

A17. The method of any of paragraphs A1-A16, wherein the sample is created via an automated process.

A18. The method of any of paragraphs A1-A16, wherein the sample is created manually by a user operator.

A19. The method of any of paragraphs A1-A18, wherein there are a greater number of template key points described by the template than a number of key points determined for the sample.

A19.1. The method of paragraph A19, further comprising: determining that there is an insufficient number of key points determined for the sample; and notifying a user that there is an insufficient number of key points.

A19.2. The method of any of paragraphs A19-A19.1, further comprising: determining an estimated accuracy of an application of the transformation based at least in part on the number of key points determined for the sample; and comparing the estimated accuracy to a threshold accuracy.

A19.2.1. The method of paragraph A19.2, wherein the sample is aligned based on the estimated accuracy being greater than the threshold accuracy.

A19.2.2. The method of paragraph A19.2, wherein when the system notifies a user that automated alignment is not possible when the estimated accuracy is less than the threshold accuracy.

A20. The method of any of paragraphs A1-A19.2.2, wherein the image is a first image, and the method further includes: generating a second image of the sample in the desired position; and verifying that the sample is in the desired position.

A20.1. The method of paragraph A20, wherein verifying comprises: determining additional key points in the second image; determining, based on the additional key points and the corresponding template key points, an additional transformation between the sample in the second image and the template version of the sample as described in the template; and verifying that the additional transformation is within a threshold value.

B1. An electron/charged particle microscope system for automatically orienting a sample in a microscope system, comprising:

a sample holder configured to hold the sample, and wherein the sample holder is configured to at least one of translate, rotate, and tilt the sample within the electron/charged particle microscope system;

a sensor configured to generate an image of the sample in the electron/charged particle microscope system;

one or more processors; and

a memory storing non-transitory computer readable instructions, that when executed by the one or more processors, cause the electron/charged particle microscope system to perform the methods of any of paragraphs A1-AX.

B1.1. The system of paragraphs B1, wherein the microscope is a charged particle microscope.

B1.2. The system of paragraphs B1, wherein the microscope is an electron charged particle microscope.

B1.3. The system of any of paragraphs B1-B1.2, wherein the microscope is a transmission microscope.

B1.4. The system of any of paragraphs B1-B1.2, wherein the microscope is a scanning microscope.

B2. The system of any of paragraphs B1-B1.4, wherein the sample holder is a sample manipulation probe.

B2.1. The system of paragraph B2.1, wherein the sample is a lamella.

B3. The system of any of paragraphs B1-B2.1, wherein the system further includes a focused ion beam (FIB) system, and wherein the electron/charged particle microscope system is further configured to generate a sub-sample/lamella from the sample once the sample is aligned in the desired position.

C1. Use of the system of B1-B3 to perform a method of any of paragraphs A1-A20.1.

The systems, apparatus, and methods described herein should not be construed as limiting in any way. Instead, the present disclosure is directed toward all novel and non-obvious features and aspects of the various disclosed embodiments, alone and in various combinations and sub-combinations with one another. The disclosed systems, methods, and apparatus are not limited to any specific aspect or feature or combinations thereof, nor do the disclosed systems, methods, and apparatus require that any one or more specific advantages be present or problems be solved. Any theories of operation are to facilitate explanation, but the disclosed systems, methods, and apparatus are not limited to such theories of operation.

Although the operations of some of the disclosed methods are described in a particular, sequential order for convenient presentation, it should be understood that this manner of description encompasses rearrangement, unless a particular ordering is required by specific language set forth below. For example, operations described sequentially may in some cases be rearranged or performed concurrently. Moreover, for the sake of simplicity, the attached figures may not show the various ways in which the disclosed systems, methods, and apparatus can be used in conjunction with other systems, methods, and apparatus. Additionally, the description sometimes uses terms like “determine,” “identify,” “produce,” and “provide” to describe the disclosed methods. These terms are high-level abstractions of the actual operations that are performed. The actual operations that correspond to these terms will vary depending on the particular implementation and are readily discernible by one of ordinary skill in the art.

What is claimed is:

1. A method for estimating position of a sample in a charged particle microscope apparatus, the method comprising:
receiving an image of the sample in the charged particle microscope apparatus;
accessing a template associated with the sample, the template describing a template version of the sample in a desired alignment, the template further including a plurality of template key points of the template version of the sample;
determining a plurality of key points on the sample, each of the key points on the sample corresponding to a corresponding template key point of a sample template;
determining, based on the key points and the corresponding template key points, a transformation between the sample in the image and the template version of the sample as described in the template; and
causing the sample to be aligned within the charged particle microscope apparatus based on the transformation.

2. The method of claim 1, wherein aligning the sample in the charged particle microscope apparatus comprises aligning the sample as part of a process in which a sub-sample/lamella is automatically formed.

3. The method of claim 1, wherein the template describes a desired region of the sample from which a sub-sample/lamella is to be formed, and aligning the sample in the charged particle microscope apparatus comprises aligning the sample so that the sub-sample/lamella is automatically formed from the desired region of the sample.

4. The method of claim 1, further comprising causing optics of the charged particle microscope apparatus to be adjusted based on the based on the key points and the corresponding template key points.

5. The method of claim 1, wherein the transformation comprises one or more of a translation, a rotation, a scale adjustment, a skew, or an application of another kind of linear transformation matrix.

6. The method of claim 1, wherein the key points are point locations within the image of the sample.

7. The method of claim 1, wherein the key points are determined using a convolutional neural network (CNN).

8. The method of claim 1, wherein determining the key points comprises:
segmenting the image to form a segmented image; and
determining the key points based on the segmented image.

9. The method of claim 1, wherein determining the plurality of key points on the sample comprises processing the image with a convolutional neural network (CNN), wherein an output of the CNN includes coordinates of predicted locations for each of the plurality of key points on the sample within the image of the sample.

10. The method of claim 1, wherein determining the transformation comprises determining a pose of the sample in the image, and then determining the transformation based on the pose.

11. The method of claim 1, wherein there is a one to one correspondence between each of the key points of the sample in the image and a corresponding template key points.

12. The method of claim 1, wherein the sample is on a probe, and wherein causing the sample to be aligned comprises manipulating the probe so that the sample is in a desired position.

13. The method of claim 1, wherein the sample is on a sample holder, and wherein causing the sample to be aligned comprises manipulating the sample holder so that the sample is in a desired position.

14. The method of claim 1, wherein the image is a first image, and the method further includes:
generating a second image of the sample after the sample has been caused to be aligned within the charged particle microscope apparatus; and
verifying, based on the second image, of that the sample is in a desired position.

15. The method of claim 14, wherein verifying that the sample is in the desired position comprises:
determining additional key points in the second image;
determining, based on the additional key points and the corresponding template key points, an additional transformation between the sample in the second image and the template version of the sample as described in the template; and
verifying that the additional transformation is within a threshold value.

16. A charged particle microscope system for automatically orienting a sample in the charged particle microscope system, comprising:
a sample holder configured to hold the sample, and wherein the sample holder is configured to at least one of translate, rotate, and tilt the sample within the charged particle microscope system;
a sensor configured to obtain sensor data used to generate an image of the sample in the charged particle microscope system;
one or more processors; and
a memory storing non-transitory computer readable instructions, that when executed by the one or more processors, cause the charged particle microscope system to:
receive the image of the sample in the charged particle microscope system;
access a template associated with the sample, the template describing a template version of the sample in a desired alignment, the template further including a plurality of template key points of the template version of the sample;
determine a plurality of key points on the sample, each of the key points on the sample corresponding to a corresponding template key point of a sample template;
determine, based on the key points and the corresponding template key points, a transformation between the sample in the image and the template version of the sample as described in the template; and
cause the sample to be aligned within the charged particle microscope system based on the transformation.

17. The charged particle microscope system of claim 16, wherein causing the sample to be aligned comprises manipulating the sample holder so that the sample is in a desired position.

18. The charged particle microscope system of claim 17, wherein the image is a first image, and the instructions further cause the charged particle microscope system to:
generate a second image of the sample in the desired position; and
verify, based on the second image, of that the sample is in the desired position.

19. The charged particle microscope system of claim 16, wherein the system further includes a focused ion beam (FIB) system, and wherein the instructions further cause the charged particle microscope system to generate a lamella from the sample once the sample is caused to be aligned within the charged particle microscope system.

20. The charged particle microscope system of claim 16, wherein the sample is a biological sample, the key points correspond to features within the biological sample, and wherein aligning the sample comprises aligning the biological sample so that the charged particle microscope system captures an additional image of a desired portion of the biological sample at a desired orientation.
